(19) United States
(12) Patent Application Publication
(10) Pub. No.: US 2006/0249656 A1
(43) Pub. Date: Nov. 9, 2006

(54) Manufacturing method for photoelectric package structure having two-layered substrate and control chip

(76) Inventors: Bily Wang, Hsin Chu City (TW); John Lin, Chia I Hsien (TW); Shih-Yu Wu, Pan Chiao City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/416,156

(22) Filed: May 3, 2006

(30) Foreign Application Priority Data
May 6, 2005 (TW) 94114754

(51) Int. Cl. H01L 27/00

(52) U.S. Cl. 250/208.1

(57) ABSTRACT

A manufacturing method for a photoelectric package structure having a two-layered substrate and a control chip is proposed. The photoelectric package structure provided in the present invention is easy for installing chips and concentrates light emitted therefrom and prevents external light interference. The package structure of the present invention is superior to the conventional ones and the installation of the control chip doesn t degrade the light-emitting intensity. The major innovation of the present invention is disposing a control chip and a photoelectric chip (or multiple photoelectric chips) on the front surfaces of two semi-finished substrates respectively and then combining with the rear surfaces of the semi-finished substrates to form a substrate. Thus, the present invention is more convenient for installing the chips. In addition, the present invention also disposes an external frame or optical gratings to prevent external light interference.

### BACKGROUND OF THE INVENTION

1. Field of the Invention

The present invention is related to a manufacturing method for a photoelectric package structure having a two-layered substrate and a control chip, and more particularly, to a manufacturing method that disposes a control chip and a photoelectric chip on the front surfaces of two semi-finished substrates respectively, combines the rear surfaces of the semi-finished substrates to form a semi-finished package structure and packages the semi-finished package structure. The light-emitting obstruction caused by chips is thereby avoided. In addition, an external frame is provided to prevent external light interference. Hence, the photoelectric package structure having a control chip provided in the present invention is superior to conventional ones.

2. Description of Related Art

In the packaging industry, the semiconductor packaging industry is one of the most important. However, since electronic products are required to be light, thin, short, small and multifunctional, the light-emitting diode (LED) and optical sensor packaging industries have also grown rapidly and also become vital. The LED or semiconductor package industry unceasingly provides new techniques, such as the ball grid array (BGA) for photoelectric chip array packaging that meets the requirements of surface mount technology (SMT). Especially, a superior substrate is needed when the number of pins is larger. Meanwhile, the brightness of packaged products is also very important.

As is known to all, electronic packaging technology is about a manufacturing process that is used to install semiconductor integrated circuits (ICs) or LEDs together with other electronic components into an electrical connecting frame to form an electronic product and thereby provide a specific function. Electronic packaging has four main purposes: power distribution, signal distribution, heat dissipation and provision of protection and support. The most often seen kind of electronic packaging is IC chip packaging and LED packaging.

Reference is made to FIG. 1, which shows a conventional photoelectric package structure having a control chip. A substrate 30a is attached with a photoelectric chip 20a and a control chip 10a. The photoelectric chip 20a and the control chip 10a are connected to the internal circuit of the substrate 30a. An external package structure is then provided to encapsulate the chips and the substrate 30a. The conventional photoelectric package structure can be use to encapsulate multiple photoelectric chips.

However, in accordance with the conventional photoelectric package structure, attaching the photoelectric chip 20a and the control chip 10a to the substrate 30a is inconvenient. Furthermore, the handling of the material is not easy either. This means that the photoelectric chip 20a and the control chip 10a should be disposed individually on the substrate 30a. The disposition procedure is complicated, occupies a larger area, and has the possibility of degrading the light-emitting efficiency. In practical applications, occupying a large area is an undesirable feature. Hence it is necessary to develop a package structure that is convenient for chip disposition and reduces the occupied area.

Accordingly, for most LEDs on the market that need substrates, a simple chip disposition procedure and a reduction in the size of the chip package are highly desirable in the packaging process. Enhancement of light intensity and prevention of external light interference are also highly desired. The present invention is provided to meet these requirements.

### SUMMARY OF THE INVENTION

An objective of the present invention is to provide a photoelectric package structure having a control chip and a manufacturing method for the same. The present invention enhances light-emitting intensity, reduces overall size and is convenient for the installing chips into a package. The photoelectric package structure provided in the present invention can be applied for backlight modules, lamps, advertising signs or electromagnetic detectors. The present invention can be used to package illuminant components, such as LEDs, or optical sensors together with a substrate and has a low cost and produces packages of high quality.

For achieving the objectives above, the present invention disposes a control chip and a photoelectric chip on front surfaces of two semi-finished substrates respectively, combines rear surfaces of the semi-finished substrates to form a semi-finished package structure and packages the semi-finished package structure. Furthermore, the above-mentioned steps of the present invention can be mainly performed by using conventional packaging procedures and uncomplicated equipment.

The manufacturing method of the present invention includes: providing a control chip and a photoelectric chip, which are installed on two semi-finished substrates to form two initial structures respectively; combing the initial structures together to form a semi-finished package structure, wherein surfaces of the semi-finished substrates not used for the installation of the chips are jointed together; and providing a package structure made of a transparent material for light transmission and disposed above the substrates to cover the photoelectric chip and the control chip. Therein the semi-finished substrates are combined to form a substrate and the substrate has an internal circuit.

Numerous additional features, benefits and details of the present invention are described in the detailed description, which follows.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 shows a conventional photoelectric package structure having a control chip;

FIG. 2 shows initial structures of the present invention;

FIG. 3 shows a photoelectric package structure with a control chip in accordance with a preferred embodiment of the present invention;

FIG. 4 shows a photoelectric package structure with a control chip in accordance with another preferred embodiment of the present invention;

FIG. 5 shows a photoelectric package structure with a control chip in accordance with another preferred embodiment of the present invention; and

FIG. 6 is a flowchart showing the operative steps of the manufacturing method in accordance with the present invention.

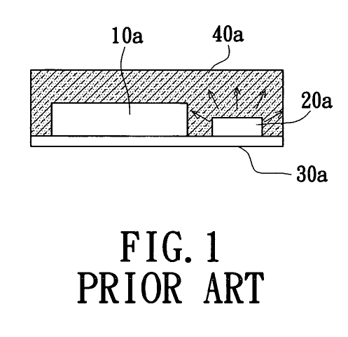

### DETAILED DESCRIPTION OF PREFERRED EMBODIMENTS

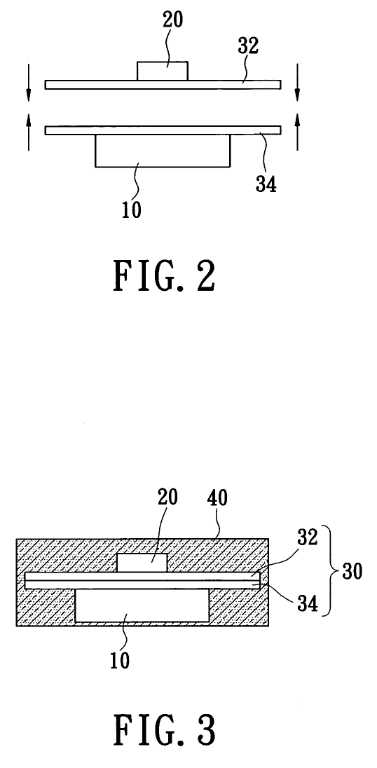

Reference is made to FIGS. 2-3, which show an embodiment of the present invention. The substrate 30 can have multiple layers. The substrate 30 is formed by combining semi-finished substrates 32 and 34. It has an upper surface and a lower surface. The upper surface is generally used for installation of a photoelectric chip 20. The photoelectric chip 20 can be an LED or an optical sensor. The substrate 10 has a circuit disposed therein. The photoelectric chip 20 is installed on the upper surface of the substrate 30. In practice, this embodiment can be applied to package multiple photoelectric chips. The control chip 10 is disposed on the lower surface of the substrate 30.

As shown in FIGS. 2-3, the photoelectric chip 20 and the control chip 10 are first disposed on the semi-finished substrates 32 and 34 respectively. The semi-finished substrates 32 and 34 are then combined to form the substrate 30. After disposition, the photoelectric chip 20 is connected to the circuit disposed inside the substrate 10.

The package structure 40 is made of a transparent material for light transmission and disposed above the substrate 30 to cover the photoelectric chip 20. Multiple contacts connecting to the internal circuit of the substrate 30 can be provided at one side or multiple predetermined sides of the substrate 30. The contacts are used for attachment to a specific electronic device. The package structure 40 is transparent and can be made of a macromolecule material that is highly transmissive, such as resin. The main structure of the present invention is shown in FIG. 2 and FIG. 3.

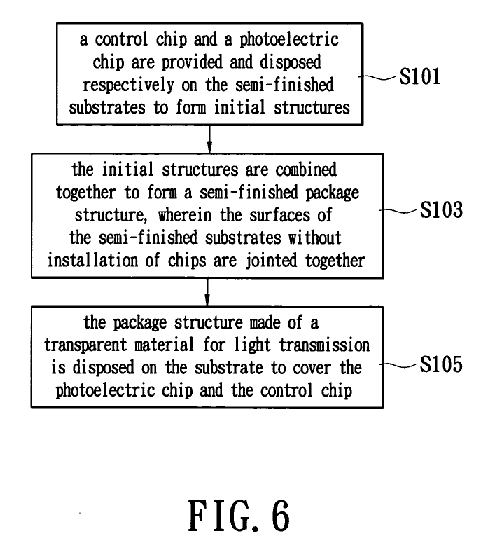

Reference is made to FIG. 6, which is a flowchart of a manufacturing method in accordance with the present invention. The manufacturing method includes the steps described as follows. A control chip 10 and a photoelectric chip 20 are provided and disposed respectively on the semi-finished substrates 32 and 34 to form initial structures as shown in FIG. 2 (S101). The initial structures are then combined together to form a semi-finished package structure as shown in FIG. 3 (S103). This means the surfaces of the semi-finished substrates 32 and 34 that do not have chips installed upon them are jointed together to form the semi-finished package structure. Finally, the package structure 40, made of a transparent material for light transmission, is disposed on the substrate 30 to cover the photoelectric chip 20 and the control chip 10. The substrate 30 has a circuit disposed inside (S105).

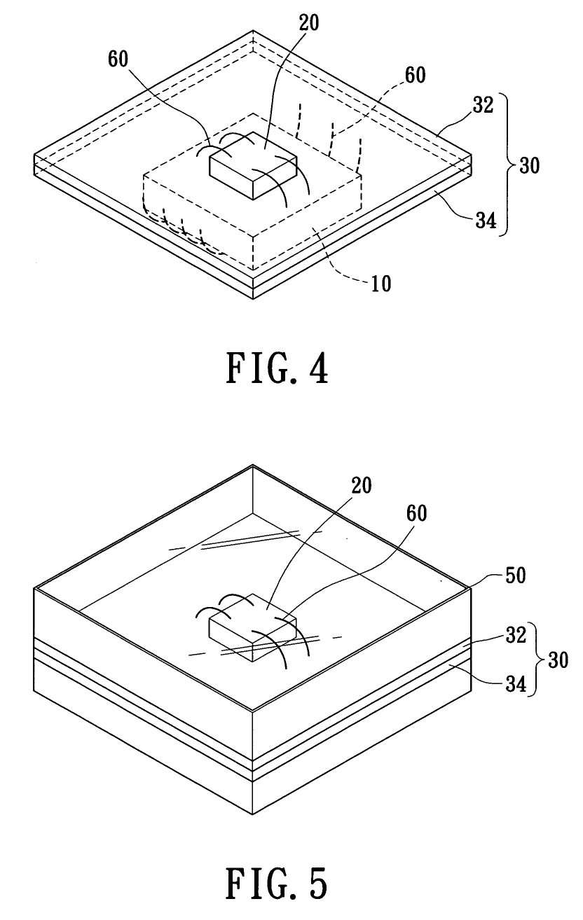

Reference is made to FIGS. 4 and 5. The embodiment of the present invention is accordingly detailed as follows. The substrate 30 can be multi-layered. It means that each of the combining semi-finished substrates 32 and 34 has multiple layers. The photoelectric chip 20 can be LEDs or optical sensors. The package structure 40 can be made of a macromolecule material. The package structure 40 can further have fluorescent powder distributed therein. The fluorescent powder can be a green or a yellow fluorescent powder or include a mixture of both.

The substrate 30 can be made of a copper circuit board. The package structure 40 can further have a reflective frame 50 surrounding thereof to prevent external light interference and reflect internal light upward. The package structure 40 can have a processed portion. The processed portion is formed with optical gratings or optical filter films for filtering or processing light. In practice, the present invention can be applied to package multiple photoelectric chips. The photoelectric chips can be arranged as an array or a totem, such as a trademark or an advertising sign. The light emitted from the photoelectric chips can be mixed to form white light. The present invention can further include multiple external contacts. The external contacts can be disposed at one side, multiple predetermined sides or the rear surface of the substrate 30 and connected to the internal circuit of the substrate 30. Furthermore, before the installation of the package structure 40, the photoelectric chip 20 and the control chip 10 can be connected to the internal circuit of the substrate 30 via metal wires 60 as shown in FIG. 4. The photoelectric chip 20 and the control chip 10 can also be connected to the internal circuit of the substrate 30 via a metal eutectic structure.

The present invention has the following features.I It is different to the conventional package structure for packaging a control chip 10 and a photoelectric chip 20. The present invention changes the deposition of the control chip 10 to avoid obstructing light emitted from the photoelectric chip 20 and is convenient for handling materials of electronic components and for assembly. External contacts can be disposed at one side, multiple predetermined sides or a rear surface of the substrate 30. A reflective frame 50 as shown in FIG. 5 or a processed portion, such as optical gratings or optical filter films for filtering or processing light emitted, can also be included. Thus, light-emitting intensity and convenience of installation of the components are improved. Furthermore, the cost is reduced and the conventional packaging procedure can be still used after slight modifications.

It should be noted that, in the present invention, the control chip 10 is disposed at a place to avoid obstructing light emitted from the photoelectric chip 20 and the mechanical equipment for this is uncomplicated, cheap and easily obtained. Thus, the present invention is easy to realize. In addition, the substrate structure of the present invention is convenient for the installation of the components and enhances light intensity. Furthermore, the conventional packaging procedure can be still applied for the present invention after slight modification. This means that the conventional packaging procedure can still be used to manufacture the present invention after some of the conventional packaging machines are modified slightly. Thus, the present invention is practical.

The present invention has the following advantages:

(1) Installation of new manufacturing equipment is easy, and the cost of the equipment and techniques needed are not high;

(2) The control chip 10 is disposed at a place to avoid obstructing light emitted from the photoelectric chip 20 and thus to reduce the overall size and improve convenience for the installation of the components;

(3) Most of conventional packaging machines are still usable; and

(4) Light-emitting intensity is enhanced and the conventional packaging procedure can still be used.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are embraced within the scope of the invention as defined in the appended claims.

What is claimed is:

1. A manufacturing method for a photoelectric package structure having a two-layered substrate and a control chip, comprising:
providing the control chip and a photoelectric chip, which are installed on two semi-finished substrates to form two initial structures respectively;
combing the initial structures together to form a semi-finished package structure, wherein surfaces of the semi-finished substrates that are not used for installation of the chips are Jointed together; and
providing a package structure made of a transparent material for light transmission and disposed above the substrates to cover the photoelectric chip and the control chip;
wherein the semi-finished substrates are combined to form a substrate and the substrate has an internal circuit.

2. The manufacturing method as claimed in claim 1, wherein the substrate has multiple layers.

3. The manufacturing method as claimed in claim 1, wherein the photoelectric chip is a light-emitting diode (LED) or an optical sensor.

4. The manufacturing method as claimed in claim 1, wherein the package structure is made of a macromolecule material.

5. The manufacturing method as claimed in claim 1, wherein the package structure further has a fluorescent powder distributed therein.

6. The manufacturing method as claimed in claim 5, wherein the fluorescent powder is a green or a yellow fluorescent powder or includes a mixture of both.

7. The manufacturing method as claimed in claim 1, wherein the substrate is made of a copper circuit board.

8. The manufacturing method as claimed in claim 1, wherein the package structure further has a reflective frame surrounding thereof.

9. The manufacturing method as claimed in claim 1, wherein the package structure further has a processed portion.

10. The manufacturing method as claimed in claim 9, wherein the processed portion is formed with optical gratings or optical filter films.

11. The manufacturing method as claimed in claim 1, further comprising multiple photoelectric chips.

12. The manufacturing method as claimed in claim 11, wherein the photoelectric chips are arranged as an array or a totem.

13. The manufacturing method as claimed in claim 11, wherein lights emitted from the photoelectric chips are mixed to form a white light.

14. The manufacturing method as claimed in claim 11, wherein the substrate has external contacts, which connect to the internal circuit and are provided at one side, multiple predetermined sides or a rear surface of the substrate.

15. The manufacturing method as claimed in claim 1, further comprising:
connecting the control chip and the photoelectric chip to the internal circuit of the substrate via metal wires before the package structure is provided.

16. The manufacturing method as claimed in claim 1, wherein the control chip and the photoelectric chip are connected to the internal circuit of the substrate via a metal eutectic structure.
